(19) United States
(12) Patent Application Publication
(10) Pub. No.: US 2007/0090517 A1
(43) Pub. Date: Apr. 26, 2007

(54) Stacked die package with thermally conductive block embedded in substrate

(76) Inventors: Sung-won Moon, Phoenix, AZ (US); Devendra Natekar, Chandler, AZ (US); Chia-pin Chiu, Tempe, AZ (US)

Correspondence Address: INTEL CORPORATION;C/O INTELLEVATE, LLC, P.O. BOX 52050, MINNEAPOLIS, MN, 55402, US

(21) Appl. No.: 11/243,809

(22) Filed: Oct. 5, 2005

(51) Int. Cl. H01L 23/34

(52) U.S. Cl. 257/706

(57) ABSTRACT

Disclosed are embodiments of a stacked die package including a thermally conductive block disposed in the substrate. The die stack may include a lower die thermally coupled with the conductive block and one or more upper die disposed on the lower die. The upper die may be electrically interconnected to one another and with the lower die by a number of thru-vias, and the die stack may also be electrically coupled with the substrate. Other embodiments are described and claimed.

### FIELD OF THE INVENTION

The disclosed embodiments relate generally integrated circuit devices and, more particularly, to the cooling of stacked die packages.

### BACKGROUND OF THE INVENTION

To meet the demands for greater integration and reduced form factors, semiconductor device manufacturers are turning to die stacking architectures and system in package (SIP) solutions. Such architectures may combine a number of electrically interconnected die arranged in a stack, and the die stack may include both memory and logic die. These stacked die packages may find use in, for example, hand-held devices such as cell phones and personal digital assistants (PDA's), as well as other computing and/or consumer electronic devices. One challenge facing manufacturers of these SIP systems is the dissipation of heat from the die stack. Operating frequencies are increasing and available features expanding and, therefore, power consumption is rising. At the same time, however, the number of stacked die may be increasing while die sizes (and overall package size) may be decreasing, resulting in higher power densities and increased thermal resistance. A failure to address these thermal loads in stacked die packages may lead to a deterioration in package performance and reliability.

### BRIEF DESCRIPTION OF THE DRAWINGS

FIG. 1 is a schematic diagram illustrating an embodiment of a stacked die package including a thermally conductive block embedded in the substrate.

FIG. 2A is a schematic diagram illustrating another embodiment of the stacked die package shown in FIG. 1.

FIG. 2B is a schematic diagram illustrating a further embodiment of the stacked die package shown in FIG. 1.

FIG. 3 is a block diagram illustrating an embodiment of a method of fabricating a stacked die package including a thermally conductive block embedded in the substrate.

FIG. 4 is a schematic diagram illustrating an embodiment an apparatus including the stacked die package of FIG. 1.

### DETAILED DESCRIPTION OF THE INVENTION

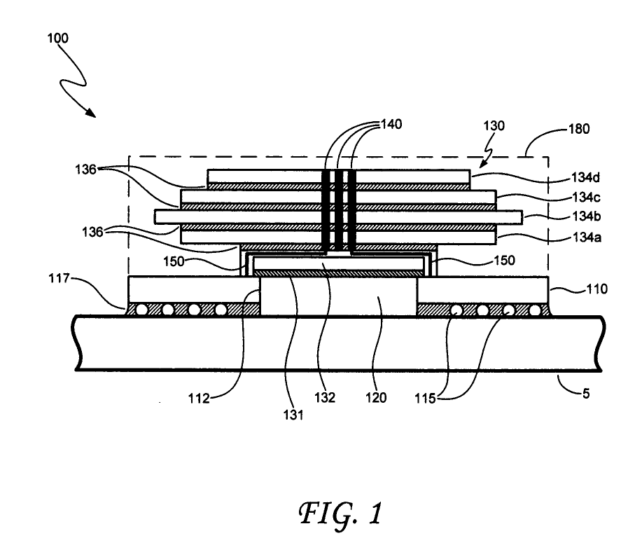

Referring to FIG. 1, illustrated is an embodiment of a stacked die package 100. The package 100 includes a substrate 110, a thermally conductive block 120 disposed in the substrate 110, and a die stack 130 disposed on the substrate 110. Package 100 may be disposed on and electrically coupled with a board 5 (e.g., a printed circuit board, or PCB) or other next-level component. The thermally conductive block 120 can provide a thermally conductive path between the die stack 130 and the board 5, which, in turn, can provide a thermally conductive path to the surrounding environment or otherwise dissipate heat generated by the die stack 130.

Substrate 110 may be electrically coupled with the board 5 and, according to one embodiment, the substrate 110 provides electrical connections between the die stack 130 and the board 5. Electrical connections between the substrate 110 and board 5 may be provided by a number of interconnects 115, such as an array of solder bumps (as shown in FIG. 1), a land grid array, a pin grid array (and mating socket on board 5), or other suitable interconnects. Also, a layer of underfill material 117 may be disposed between the substrate 110 and board 5.

Substrate 110 may comprise any suitable substrate or other die carrier upon which the die stack 130 can be disposed. In one embodiment, the substrate 110 comprises a multilayer substrate including a number of alternating layers of metallization and dielectric material. Each layer of metallization comprises a number of conductors (e.g., traces), and these conductors may comprise any suitable conductive material, such as copper. Further, each metal layer is separated from adjacent metal layers by the dielectric layers, and adjacent metal layers may be electrically interconnected by conductive vias. The dielectric layers may comprise any suitable insulating material—e.g., polymers, including both thermoplastic and thermosetting resins or epoxies, ceramics, etc.—and the alternating layers of metal and dielectric material may be built-up over a core layer of a dielectric material.

Thermally conductive block 120 may comprise any suitable thermally conductive material. In one embodiment, the block 120 comprises copper or a copper alloy. However, the composition of the thermally conductive block 120 is not limited to copper (or to metals), and the block may comprise any other suitable material (or combination of materials), such as aluminum, silicon, thermally conductive composite materials, etc. Also, the thermally conductive block may have any suitable size and shape. In one embodiment, the thickness of block 120 is sufficient to provide a thermally conductive path between the die stack 130 and the board 5. According to another embodiment, the shape of the block 120 provides a periphery that lies, at least in part, within a periphery of a lower die in the die stack 130, such that electrical connections can be established between the die stack and substrate 110. Any suitable technique and/or device may be utilized to thermally couple the block 120 with board 5, including, by way of example, a thermally conductive epoxy (or other thermally conductive polymer), a composite material, or solder (this material layer not shown in the figures). The block 120 may be secured in the substrate 110 using any suitable technique and/or device. According to one embodiment, an aperture 112 is formed in substrate 110, and the thermally conductive block 120 is inserted into and secured within this aperture (e.g., by an adhesive, using a press fit, etc.). In another embodiment, the substrate 110 may be built-up around the block 120.

Die stack 130 may comprise any suitable number and combination of integrated circuit die. In one embodiment, the die stack 130 includes a lower die 132 and a number of upper die 134 (including, for example, upper die 134a, 134b, 134c, 134d) disposed on the lower die. The lower die 132 is thermally coupled with the thermally conductive block 120. Any suitable technique and/or device may be employed to thermally couple the lower die 132 with block 120, including, for example, a layer 131 of a thermally conductive epoxy (or other thermally conductive polymer), a composite material, or a solder. A layer of adhesive 136 may be used to attach the upper die 134 to one another as well as to the lower die 132 and, in one embodiment, the adhesive 136 is thermally conductive. Also, in one embodiment, a molding material 180 (shown by dashed lines) may be disposed over the die stack 130 and substrate 110.

According to one embodiment, a number of thru-vias 140 extend through and eletrically interconnect the upper die 134a-d. The thru-vias 140 may terminate at the lower die 132 and may be electrically coupled to the lower die. Any suitable number of thru-vias 140 (e.g., one or more) may be used to interconnect the upper die 134. Thru-vias 140 may be formed using any suitable process, such as, for example, etching, laser drilling, or mechanical drilling, and these vias may be formed either before or after the upper die are secured to one another. In one embodiment, as shown in FIG. 1, the thru-vias 140 are located proximate the centers of the upper die 134; however, in other embodiments, these vias may be located away from the die centers. It should be understood that interconnection of the die within die stack 130 is not limited to use of thru-vias 140, and in other embodiments alternative techniques for interconnecting die within the die stack may be utilized (e.g., wirebonding, etc.).

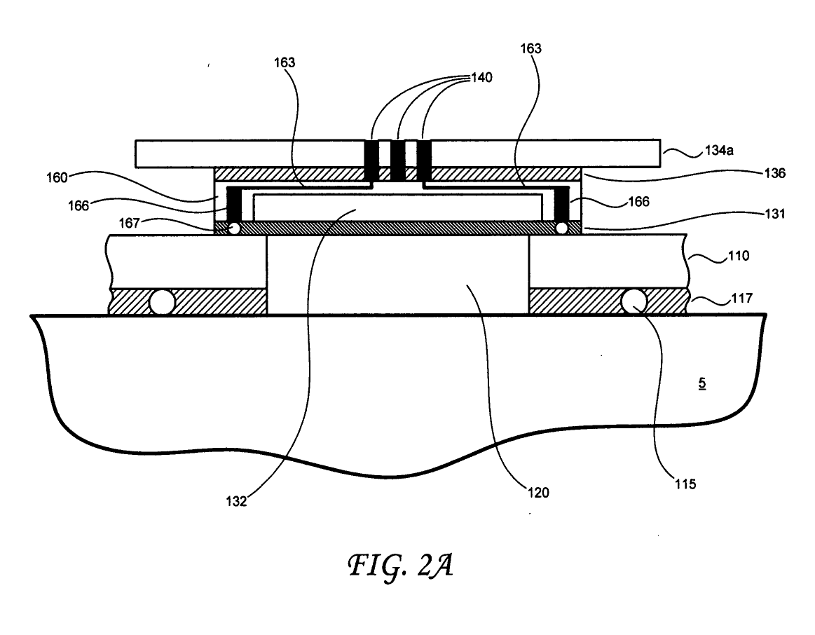

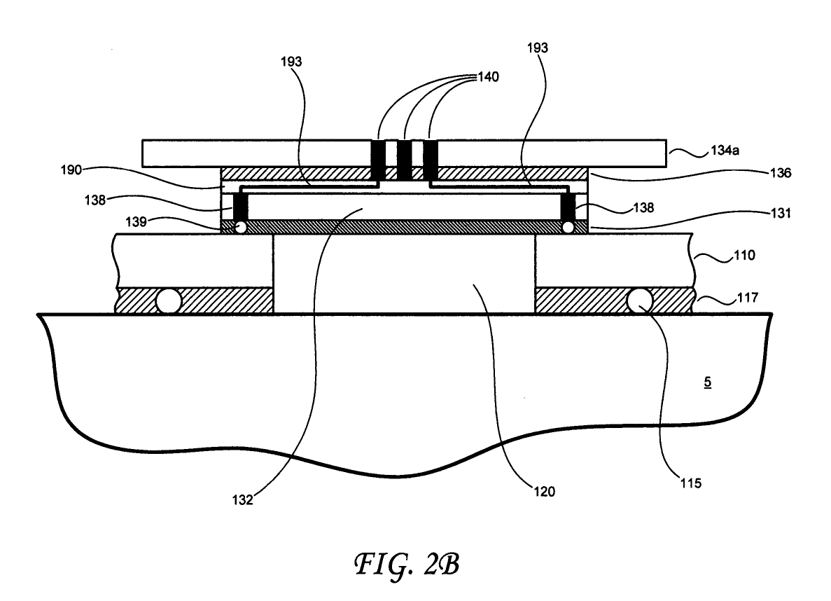

The die stack 130 is electrically coupled with the substrate 110 by one or more conductors 150. As noted above, the substrate 110 may, in turn, electrically couple the stacked die package 100 to the board 5. Any suitable number, combination, and/or configuration of conductors 150 may be employed to electrically couple the die stack 130 with the substrate 110, and various embodiments of these conductors are described below in FIGS. 2A and 2B and the accompanying text.

As previously noted, die stack 130 may comprise any suitable number and combination of die. According to one embodiment, the lower die 132 comprises a logic device and the upper die 134 comprise memory devices (e.g., flash memory). In one embodiment, the lower die 132 includes a memory controller unit for the upper die 134. It should be understood, however, that these are but a few examples of the types of die that can be combined in die stack 130 and, further, that other combinations of die and/or circuitry may be utilized, as desired. For example, in other embodiments, the lower die 132 may comprise a processing device (e.g., a microprocessor, a network processor, etc.) and each of the upper die 134 a type of dynamic random access memory (DRAM), such as double data rate DRAM (DDRDRAM) or synchronous DRAM (SDRAM), and/or a type of static random access memory (SRAM). According to other embodiments, the die stack 130 may include RF and other wireless devices and/or circuits.

Turning now to FIG. 2A, in one embodiment, the die stack 130 may be electrically coupled with the substrate 110 using a redistribution layer 160. The redistribution layer 160 is electrically coupled with both the thru-vias 140 and the lower die 132, and redistribution layer 160 includes one or more conductors 163 to route signal lines out to vias 166 within the redistribution layer, which may be electrically coupled to substrate 110 by solder bumps 167 (or other suitable interconnects). A periphery of the redistribution layer 160 extends, at least in part, beyond a periphery of the thermally conductive block, such that vias 166 overly substrate 110.

The redistribution layer 160 may include any suitable structure capable of electrically coupling the die stack 130 to substrate 110. According to one embodiment, the redistribution layer 160 comprises multiple alternating layers of metallization and dielectric material. Each layer of metallization comprises a number of conductors (e.g., traces), and these conductors may comprise any suitable conductive material, such as copper. Further, each metal layer is separated from adjacent metal layers by the dielectric layers, and adjacent metal layers may be electrically interconnected by conductive vias. The dielectric layers may comprise any suitable insulating material—e.g., polymers, including both thermoplastic and thermosetting resins or epoxies, ceramics, etc.—and the alternating layers of metal. The redistribution layer 160 may be formed separately and disposed over and/or around the lower die 132 or, alternatively, the redistribution layer 160 may be built-up around and/or over the lower die 132.

Referring next to FIG. 2B, in another embodiment, a periphery of the lower die 132 extends, at least in part, beyond the periphery of the thermally conductive block 120, and one or more thru-vias 138 located proximate the lower die's periphery overly the substrate 110. The lower die 132 includes an interconnect structure 190, and one or more conductors 193 disposed in the interconnect structure route signal lines from the lower die 132 and thru-vias 140 (and upper die 134) to the thru-vias 138 in the lower die 132. In turn, these thru-vias 138 in the lower die route these signal lines to the substrate 110. Thru-vias 138 may be electrically coupled with the substrate 110 by solder bumps 139 (or other suitable interconnects).

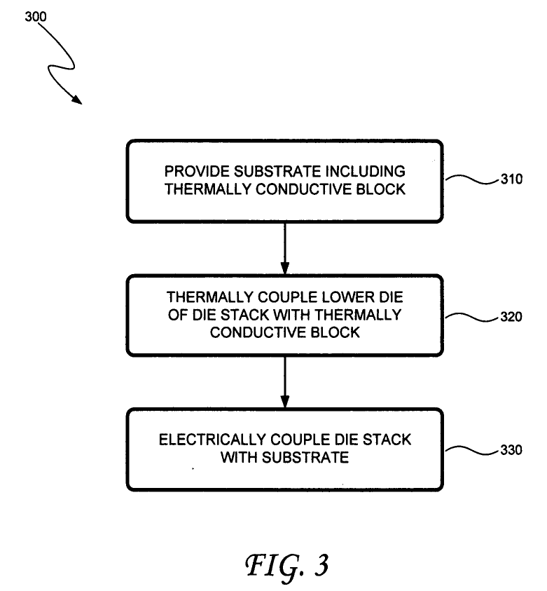

Illustrated in FIG. 3 is an embodiment of a method of fabricating a stacked die package including a thermally conductive block embedded in the substrate. Referring to block 310 in this figure, a substrate is provided that includes a thermally conductive block, as described above. As set forth in block 320, a lower die of a die stack is thermally coupled with the thermally conductive block in the substrate, as also described above. With reference to block 330, the die stack is electrically coupled with the substrate. In one embodiment, the die stack is electrically coupled with the substrate using a redistribution layer, and in another embodiment the die stack is electrically coupled with the substrate using one or more thru-vias formed proximate a periphery of the lower die in the stack, both as previously described. It should, however, be understood that other methods and/or devices may be utilized to form electrical connections between the die stack and the substrate.

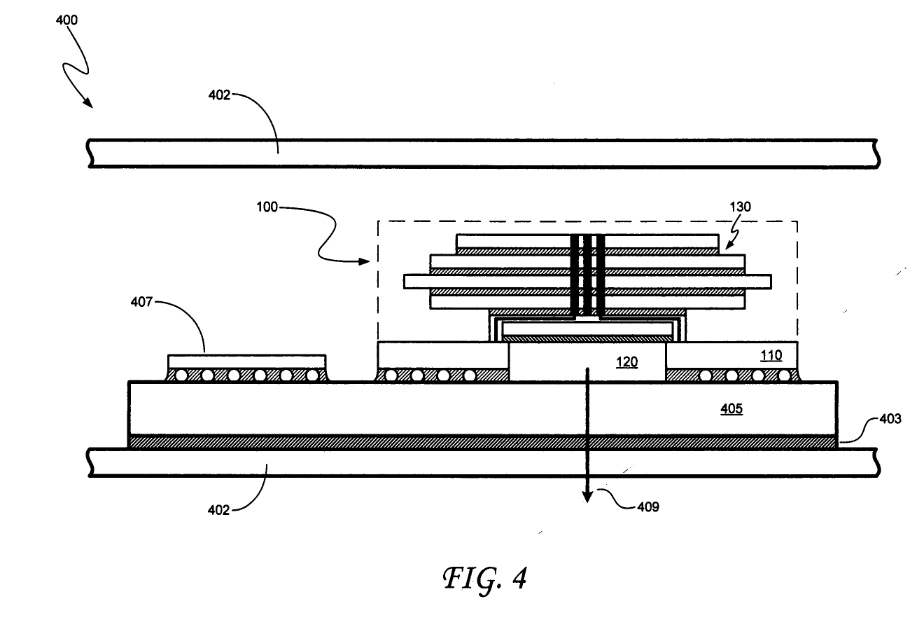

Referring now to FIG. 4, illustrated is an embodiment of an apparatus 400 including a stacked die package having a thermally conductive block underlying the die stack. The apparatus 400 includes a housing 402 or other enclosure, and this housing may be constructed from any suitable material or combination of materials, including metals, plastics, composites, etc. In one embodiment, the housing 402 is constructed from a material that is thermally conductive. Disposed within the housing 402 is a board 405 or other suitable substrate (e.g., a printed circuit board). According to one embodiment, the board 405 is both mechanically attached and thermally coupled with the housing 402. For example, the board 405 may be mechanically and thermally coupled to the housing 402 using a layer of thermally conductive epoxy 403 (e.g., a silicon-based polymer with a boron nitride filler) or other suitable adhesive.

Disposed on the board 405 is a stacked die package 100 including a thermally conductive block 120, as described above. The block 120 provides a thermally conductive path between the die stack 130 and the board 405. In turn, the board 405, conductive epoxy 403, and housing 402 may provide a thermally conductive path out of the housing 402 (see arrow 409), where heat can be dissipated to the ambient environment (e.g., by convection and/or radiation). It should be understood that the apparatus 400 may employ other modes of cooling in addition to the above-described thermal conduction.

In addition to stacked package 100, other components may be disposed on the board 405. For example, as shown in FIG. 4, a component 407 may be disposed on board 405, and the board may provide electrical connections between the component 407 and stacked package 100. The component 407 may comprise any desired device, such as an integrated circuit die (e.g., a processor, a memory, a chip set, a voltage regulator, an RF device, a wireless communications device, etc.) or a discrete electrical device (e.g., a capacitor, inductor, etc.). Further, the apparatus 100 may comprise any type of system, including, for example, a hand-held device such as a cell phone or PDA, as well as any other computing and/or consumer electronic device.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. A package comprising:
a substrate;
a thermally conductive block disposed in the substrate; and
a die stack disposed on the substrate, the die stack including a lower die thermally coupled with the block and a number of upper die disposed on the lower die, the upper die interconnected by a via;
wherein the die stack is electrically coupled with the substrate.

2. The package of claim 1, wherein the substrate includes an aperture and the thermally conductive block is disposed in the aperture.

3. The package of claim 1, wherein the thermally conductive block provides a thermally conductive path between the lower die and a next-level component.

4. The package of claim 3, wherein the next-level component comprises a printed circuit board.

5. The package of claim 3, wherein the substrate is electrically coupled with the next level component.

6. The package of claim 1, wherein the lower die comprises a logic device and each of the upper die comprises a memory device.

7. The package of claim 1, wherein the upper die are electrically interconnected by two or more vias.

8. The package of claim 1, further comprising a redistribution layer electrically coupled with the via and the lower die, the redistribution layer including a conductor electrically coupling the die stack to the substrate.

9. The package of claim 1, wherein the lower die includes:
a number of thru-vias disposed about a periphery of the lower die; and
an interconnect structure electrically coupled with the via, the interconnect structure including at least one conductor electrically coupled with one of the thru-vias.

10. The package of claim 1, further comprising a mold compound disposed over the die stack and the substrate.

11. An apparatus comprising:
a housing; and
a system disposed in the housing, the system including
a board thermally coupled with the housing, and
a package disposed on the board, the package including a substrate, a thermally conductive block disposed in the substrate, and a die stack electrically coupled with the substrate, the die stack including a lower die thermally coupled with the block and a number of upper die disposed on the lower die, the upper die interconnected by a via,
wherein the block provides a thermally conductive path between the die stack and the board.

12. The apparatus of claim 11, wherein the board is thermally coupled with the housing by a layer of thermally conductive epoxy, and the board, thermally conductive epoxy, and housing provide a thermally conductive path to the ambient environment.

13. The apparatus of claim 11, further comprising a second component disposed on the board.

14. The apparatus of claim 13, wherein the second component comprises a device selected from a group consisting of a processor, a memory, a chip set, a voltage regulator, an RF device, a wireless communications device, and a discrete electrical device.

15. The apparatus of claim 11, wherein the substrate includes an aperture and the thermally conductive block is disposed in the aperture.

16. The apparatus of claim 11, wherein the lower die comprises a logic device and each of the upper die comprises a memory device.

17. The apparatus of claim 11, wherein the upper die are electrically interconnected two or more vias.

18. The apparatus of claim 11, further comprising a redistribution layer electrically coupled with the via and the lower die, the redistribution layer including a conductor electrically coupling the die stack to the substrate.

19. The apparatus of claim 11, wherein the lower die includes:
a number of thru-vias disposed about a periphery of the lower die; and
an interconnect structure electrically coupled with the via, the interconnect structure including at least one conductor electrically coupled with one of the thru-vias.

20. A method comprising:
providing a substrate including a thermally conductive block;
thermally coupling a lower die of a die stack with the thermally conductive block, the die stack including a number of upper die disposed on the lower die, the upper die interconnected by a via; and
electrically coupling the die stack to the substrate.

21. The method of claim 20, wherein the substrate includes an aperture and the thermally conductive block is disposed in the aperture.

22. The method of claim 20, further comprising electrically coupling the substrate to a next-level component, the thermally conductive block providing a thermally conductive path between the lower die and the next-level component.

23. The method of claim 22, wherein the next-level component comprises a printed circuit board.

24. The method of claim 20, wherein the lower die comprises a logic device and each of the upper die comprises a memory device.

25. The method of claim 20, wherein the upper die are electrically interconnected two or more vias.

26. The method of claim 20, wherein electrically coupling the die stack to the substrate comprises providing a redistribution layer electrically coupled with the via and the lower die, the redistribution layer including a conductor electrically coupling the die stack to the substrate.

27. The method of claim 20, wherein electrically coupling the die stack to the substrate comprises:
providing a number of thru-vias disposed about a periphery of the lower die; and
providing an interconnect structure on the lower die, the interconnect structure electrically coupled with the via and including at least one conductor electrically coupled with one of the thru-vias.
